(19) United States
(12) Patent Application Publication
(10) Pub. No.: US 2026/0362604 A1
(43) Pub. Date: Nov. 12, 2026

(54) MOTHERBOARD MODULE

(71) Applicant: MICRO-STAR INTERNATIONAL CO., LTD., New Taipei City (TW)

(72) Inventors: Chung-Hsing Chang, New Taipei City (TW); CHIEN-HAO HUANG, New Taipei City (TW); Min-Chung Hsueh, New Taipei City (TW); KAI-JUN ZHANG, New Taipei City (TW); Bo-Wen Chang, New Taipei City (TW); YU-JU CHOU, New Taipei City (TW); CHIA-YING CHANG, New Taipei City (TW); Kai-Jun Lei, New Taipei City (TW); Liang-Xiong Pang, New Taipei City (TW)

(21) Appl. No.: 19/356,175

(22) Filed: Oct. 12, 2025

Related U.S. Application Data
(60) Provisional application No. 63/801,146, filed on May 7, 2025.

(51) Int. Cl. H05K 1/184; H05K 3/341

(52) U.S. Cl. CPC H05K 1/184; H05K 3/3415; H05K 2201/095; H05K 2201/10325

(57) ABSTRACT

A motherboard module includes a motherboard, multiple solders arranged in the motherboard, and multiple electronic components that are inserted into the motherboard and the solders. The motherboard defines a handheld boundary that is located inside of a surrounding lateral surface of the motherboard by a distribution distance within a range from 2 cm to 8 cm. The motherboard has a handheld region that is located between the handheld boundary and the surrounding lateral surface and that has multiple thru-holes recessed therein. The electronic components have multiple pins that are respectively inserted into the thru-holes of the handheld region, and a free end of each of the pins is embedded in a corresponding one of the solders. Each of the pins has an embedded depth that is within a range from 75% to 95% of a hole depth of a corresponding one of the thru-holes.

### CROSS-REFERENCE TO RELATED PATENT APPLICATION

This application claims the benefit of priority to the U.S. Provisional Patent Application Ser. No. 63/801,146, filed on May 7, 2025, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an electronic module, and more particularly to a motherboard module.

### BACKGROUND OF THE DISCLOSURE

A conventional motherboard module includes a motherboard and a plurality of electronic components that are mounted on the motherboard. Pins of the electronic components pass through the motherboard and have sharp free ends that are exposed from the motherboard, such that the conventional motherboard module is easy to cause injuries when being held by people.

### SUMMARY OF THE DISCLOSURE

In response to the above-referenced technical inadequacies, the present disclosure provides a motherboard module for effectively improving on the issues associated with conventional motherboard modules.

In order to solve the above-mentioned problems, one of the technical aspects adopted by the present disclosure is to provide a motherboard module, which includes a motherboard, a plurality of solders, and a plurality of electronic components. The motherboard has a first surface, a second surface being opposite to the first surface, and a surrounding lateral surface that is connected to an edge of the first surface and an edge of the second surface. The motherboard defines a handheld boundary that is arranged inside of and spaced apart from the surrounding lateral surface by a distribution distance being within a range from 2 cm to 8cm. The motherboard has a handheld region arranged between the handheld boundary and the surrounding lateral surface. The handheld region has a plurality of thru-holes recessed from the first surface to the second surface. The solders are spaced apart from each other, and are respectively filled in the plurality of thru-holes. The electronic components have a plurality of pins. The plurality of pins of the plurality of electronic components are respectively inserted into the plurality of thru-holes of the handheld region from the first surface to the second surface, and a free end of each of the plurality of pins is embedded in a corresponding one of the plurality of solders. The free end of each of the plurality of pins is spaced apart from the first surface by an embedded depth that is within a range from 75% to 95% of a hole depth of a corresponding one of the plurality of thru-holes.

Therefore, the motherboard module in the present disclosure is provided with the handheld region that is pre-planned for forming the thru-holes, and the embedded depth of each of the pins for a corresponding one of the thru-holes is controlled to be within a specific ratio (e.g., the embedded depth being within a range from 75% to 95% of the hole depth), so that each of the pins does not protrude from the second surface of the handheld region that is habitually hand-held by the user, thereby enabling the motherboard module to have a hand-protection (or anti-prick) function and effectively preventing the pins from causing injury to the user.

Specifically, while the motherboard module of the present disclosure is provided with the hand-protection function, the embedded depth of each of the pins is controlled to be greater than or equal to 75% of the hole depth, so that each of the pins can be maintained to have a sufficient area for contacting a corresponding one of the solders, thereby allowing each of the pins to be stably fixed to the motherboard through a corresponding one of the solders.

These and other aspects of the present disclosure will become apparent from the following description of the embodiment taken in conjunction with the following drawings and their captions, although variations and modifications therein may be effected without departing from the scope of the novel concepts of the disclosure.

### BRIEF DESCRIPTION OF THE DRAWINGS

The described embodiments may be better understood by reference to the following description and the accompanying drawings, in which:

FIG. 1 is a schematic planar view of a motherboard module according to one embodiment of the present disclosure;

FIG. 2 is a schematic planar view of the motherboard module from another angle of view according to the embodiment of the present disclosure;

FIG. 3 is a schematic cross-sectional view taken along line III-III of FIG. 2;

FIG. 4 is a schematic cross-sectional view showing a first variation of a structure shown in FIG. 3;

FIG. 5 is a schematic cross-sectional view showing a second variation of the structure shown in FIG. 3; and

FIG. 6 is a schematic cross-sectional view showing a third variation of the structure shown in FIG. 3.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

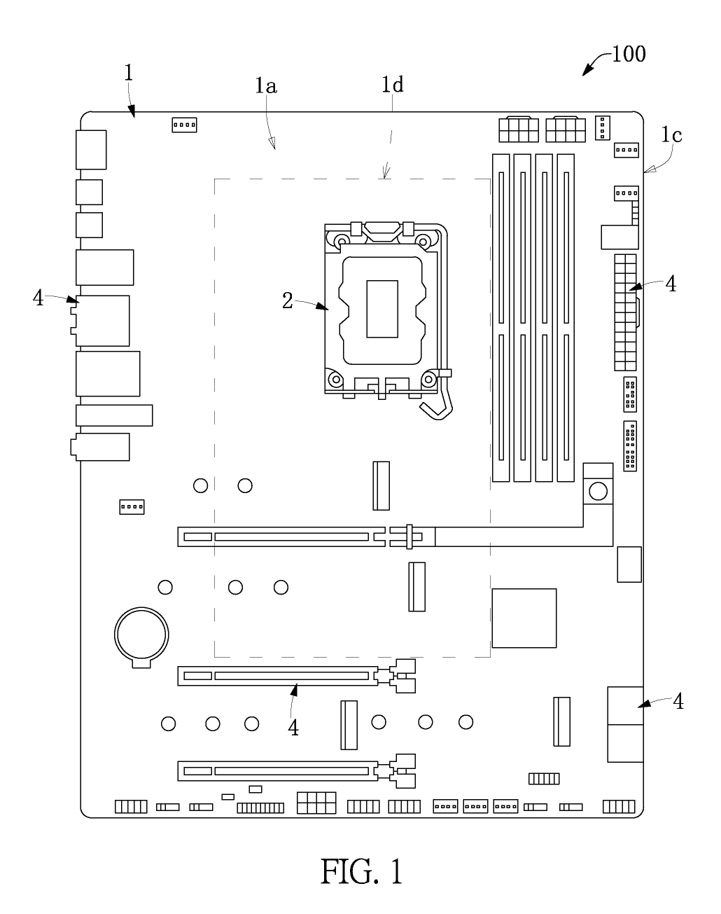

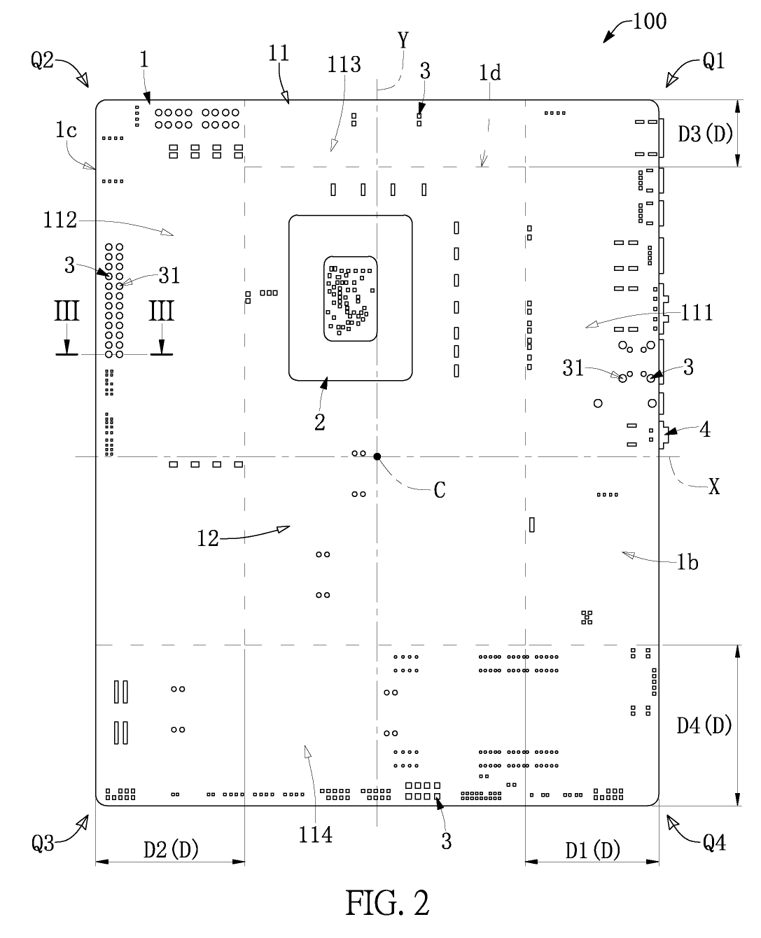

Referring to FIGS. 1-6, an embodiment of the present disclosure is provided. As shown in FIGS. 1-4, the present embodiment provides a motherboard module 100, which includes a motherboard 1, a processor socket 2 mounted on the motherboard 1, a plurality of solders 3 disposed on the motherboard 1, and a plurality of electronic components 4 that are inserted into the motherboard 1 and the solders 3, but the present disclosure is not limited thereto. For example, in other embodiments of the present disclosure not shown in the drawings, the processor socket 2 can be omitted or can be replaced by other components according to practical requirements.

In the present embodiment, the motherboard 1 has a substantially rectangular shape, and has a first surface 1a, a second surface 1b being opposite to the first surface 1a, and a surrounding lateral surface 1c that is connected to an edge of the first surface 1a and an edge of the second surface 1b. The motherboard 1 defines a handheld boundary 1d that is arranged inside of and spaced apart from the surrounding lateral surface 1c by a distribution distance D being within a range from 2cm to 8cm.

Specifically, the motherboard 1 has a handheld region 11 that is arranged between the handheld boundary 1d and the surrounding lateral surface 1c, and has a central region 12 that is surrounded by the handheld boundary 1d. In the present embodiment, the central region 12 has a substantially rectangular shape, and its area is less than an area of the handheld region 11 that is ring-shaped. The area of the central region 12 can be within a range from 20% to 30% (e.g., 24.7% to 24.8%) of the area of the handheld region 11. In one practical embodiment of the present disclosure, the area of the central region 12 can be calculated by the following equation: 90 mm × 203 mm = 18,270 mm², and the area of the handheld region 11 can be calculated by the following equation: 243 mm × 304.8 mm = 73,872 mm², but the present disclosure is not limited thereto. For example, in other embodiments of the present disclosure not shown in the drawings, the area of the central region 12 can be greater than or equal to the area of the handheld region 11 according to practical requirements.

In the present embodiment, the processor socket 2 is fixed to the central region 12, and the handheld region 11 has a plurality of thru-holes 115 recessed from the first surface 1a to the second surface 1b. In other words, a hole depth T115 of each of the thru-holes 115 is equal to a thickness of the motherboard 1, and the thru-holes 115 can have a same aperture or different apertures according to practical requirements. The present disclosure is not limited thereto.

Moreover, the solders 3 are spaced apart from each other, and are respectively filled in the thru-holes 115. The electronic components 4 have a plurality of pins 41. A specific structure of at least one of the pins 41 of each of the electronic components 4 can be adjusted or changed according to practical requirements, and is not limited by the present embodiment. The pins 41 of the electronic components 4 are respectively inserted into the thru-holes 115 of the handheld region 11 from the first surface 1a to the second surface 1b, and a free end 411 of each of the pins 41 is embedded in a corresponding one of the solders 3.

Specifically, the free end 411 of each of the pins 4 is spaced apart from the first surface 1a by an embedded depth T41 that is within a range from 75% to 95% of the hole depth T115 of a corresponding one of the thru-holes 115. For example, when the thickness of the motherboard 1 is 1.6 mm, the embedded depth T41 can be within a range from 1.2 mm to 1.5 mm, but the present disclosure is not limited thereto.

Based on the above, in the motherboard module 100 of the present embodiment, the thru-holes 115 are formed in the handheld region 11 that is pre-planned, and the embedded depth T41 of each of the pins 41 for the corresponding thru-hole 115 is controlled to be within a specific ratio, so that each of the pins 41 does not protrude from the second surface 1b of the handheld region 11 that is habitually hand-held by the user, thereby enabling the motherboard module 100 to have a hand-protection (or anti-prick) function to effectively prevent the pins 41 from causing injury to the user.

Specifically, while the motherboard module 100 is provided with the hand-protection function, the embedded depth T41 of each of the pins 41 is controlled to be greater than or equal to 75% of the hole depth T115, so that each of the pins 41 can be maintained to have a sufficient area for contacting a corresponding one of the solders 3, thereby allowing each of the pins 41 to be stably fixed to the motherboard 1 through a corresponding one of the solders 3.

Since the embedded depth T41 of each of the pins 41 is controlled to be greater than or equal to 75% of the hole depth T115, when any of the electronic components 4 is affected by an external force, a corresponding one of the pins 41 can have a sufficient length to be combined with the solder 3, thereby effectively avoiding looseness between each of the pins 41 and a corresponding one of the solders 3.

Apart from embedding the free end 411 of each of the pins 41 within a corresponding one of the solders 3 to achieve the hand-protection function, the motherboard module 100 in the present embodiment further improves the structure of a touch end 31 of each of the solders 3 adjacent to (or exposed from) the second surface 1b to further enhance a grip feel of the handheld region 11. The following description describes several possible configurations of the touch end 31, but the present disclosure is not limited thereto.

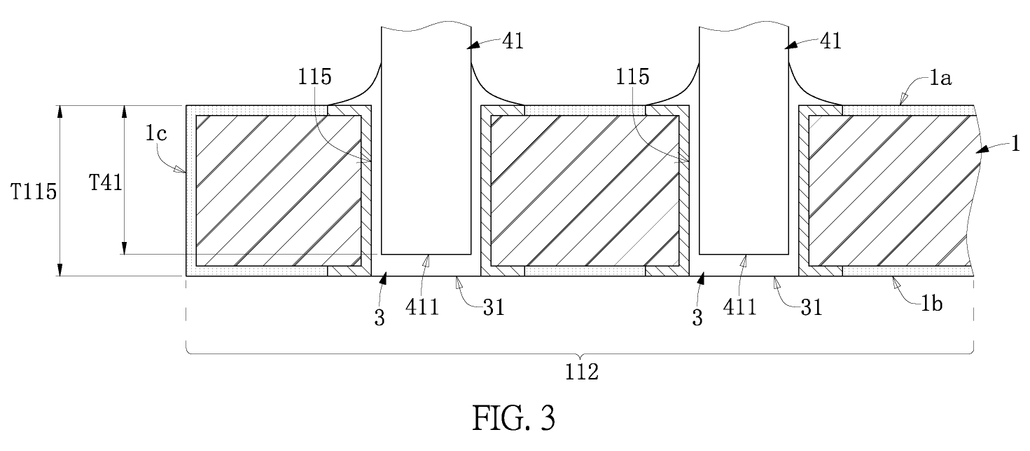

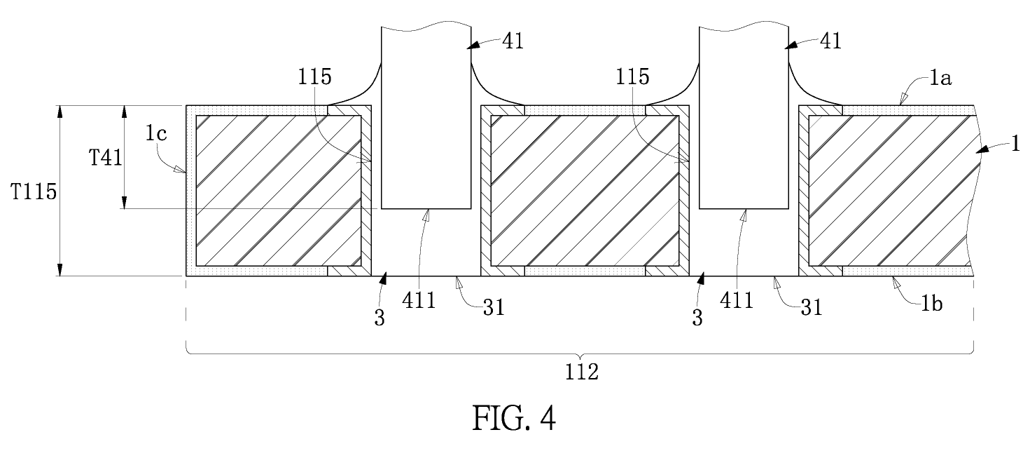

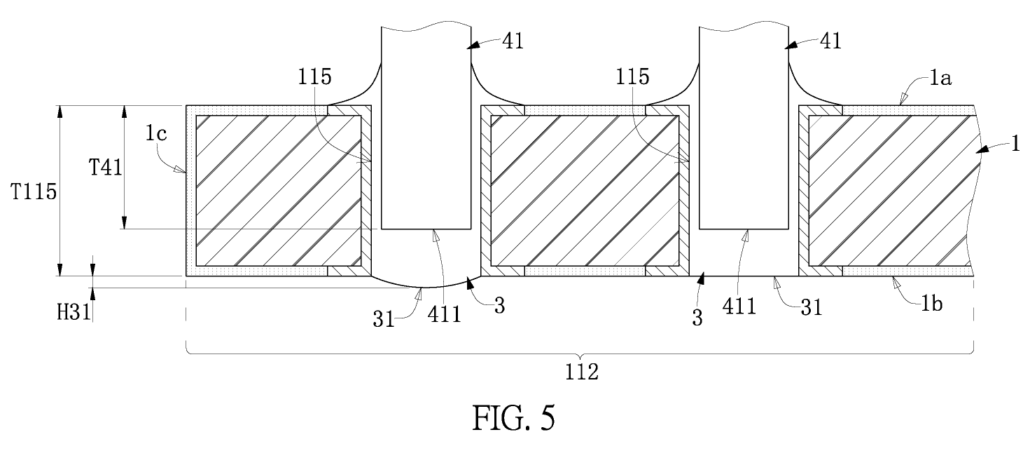

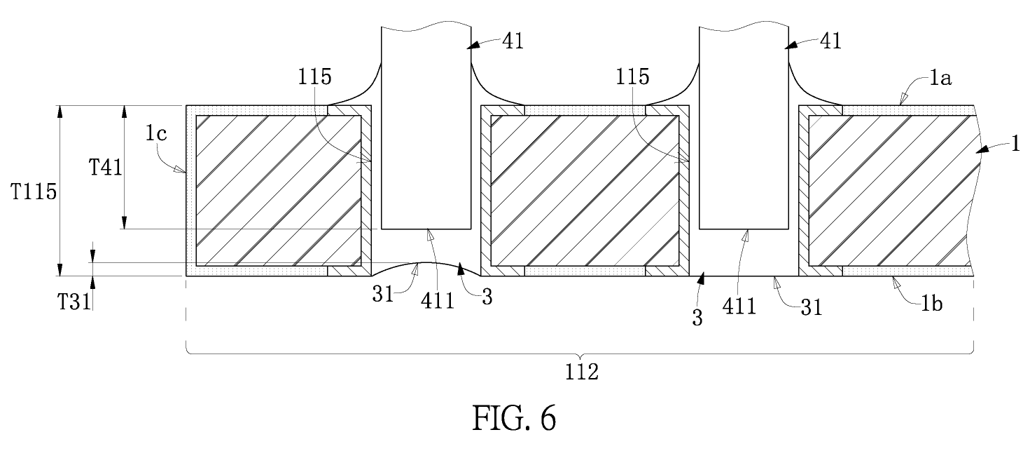

As shown in FIGS. 3 and 4, the touch end 31 of each of the solders 3 has a planar (or flat) shape, and the touch ends 31 of the solders 3 are coplanar with the second surfaces 1b. Alternatively, as shown in FIG. 5, the touch end 31 of at least one of the solders 3 has a convex surface relative to the second surface 1b, and a height H31 of the convex surface relative to the second surface 1b is less than or equal to 1.5 mm. Alternatively, as shown in FIG. 6, the touch end 31 of at least one of the solders 3 has a concave surface relative to the second surface 1b, and a depth T31 of the concave surface relative to the second surface 1b is less than or equal to 1.125 mm. For example, the depth T31 can be less than or equal to 0.1 mm, or can be within a range from 0.9 mm to 1.125 mm.

It should be noted that although the specific planning and coverage of the handheld region 11 can have various configurations according to practical requirements, the handheld region 11 is actually related to the position of the processor socket 2 and the specific appearance of the motherboard 1. Accordingly, the following descriptions of the present embodiment illustrate one of the preferred configurations of the handheld region 11 and its corresponding components, but the present disclosure is not limited thereto.

As shown in FIGS. 1-4, the handheld region 11 of the present embodiment includes a first subregion 111 arranged at one side of the processor socket 2, a second subregion 112 arranged at another side of the processor socket 2, a third subregion 113 that is connected in-between one end of the first subregion 111 and one end of the second subregion 112 and is arranged adjacent to the processor socket 2, and a fourth subregion 114 that is connected in-between another end of the first subregion 111 and another end of the second subregion 112 and is arranged away from the processor socket 2.

The first subregion 111 and the second subregion 112 each have a rectangular shape and are respectively located at two opposite sides of the processor socket 2, and the third subregion 113 and the fourth subregion 114 each have a rectangular shape and are respectively located at another two opposite sides of the processor socket 2.

In the present embodiment, the first subregion 111 and the second subregion 112 respectively correspond in position to two long lateral edges of the motherboard 1, and correspond in position to a part of one of two short lateral edges of the motherboard 1. The third subregion 113 corresponds in position to another part of the one of the two short lateral edges of the motherboard 1, and the fourth subregion 114 corresponds in position to another one of the two short lateral edges of the motherboard 1.

Specifically, the distribution distance D corresponding to the first subregion 111 is defined as a first distribution distance D1 that is within a range from 6 cm to 8 cm, the distribution distance D corresponding to the second subregion 112 is defined as a second distribution distance D2 that is within a range from 2 cm to 8 cm, the distribution distance D corresponding to the third subregion 113 is defined as a third distribution distance D3 that is within a range from 2 cm to 5 cm, and the distribution distance D corresponding to the fourth subregion 114 is defined as a fourth distribution distance D4 that is within a range from 6 cm to 8 cm, but the present disclosure is not limited thereto.

In addition, a counterweight of the motherboard module 100 in the first subregion 111 (e.g., a total weight of the first subregion 111, the electronic components 4 that are mounted thereon, and the solders 3 that are formed thereon) is greater than any one of a counterweight of the motherboard module 100 in the second subregion 112, a counterweight of the motherboard module 100 in the third subregion 113, and a counterweight of the motherboard module 100 in the fourth subregion 114. Moreover, a quantity of the thru-holes 115 in the first subregion 111 is greater than any one of a quantity of the thru-holes 115 in the second subregion 112, a quantity of the thru-holes 115 in the third subregion 113, and a quantity of the thru-holes 115 in the fourth subregion 114.

In other words, the motherboard 1 of the present embodiment defines a transversal axis X and a longitudinal axis Y that is intersected with the transversal axis X at a center C thereof so as to sequentially divide the motherboard 1 into a first quadrant Q1, a second quadrant Q2, a third quadrant Q3, and a fourth quadrant Q4 (in a counterclockwise direction) through the transversal axis X and the longitudinal axis Y.

The first subregion 111 is arranged in the first quadrant Q1 and the fourth quadrant Q4, the second subregion 112 is arranged in the second quadrant Q2 and the third quadrant Q3, the third subregion 113 is arranged in the first quadrant Q1 and the second quadrant Q2, and the fourth subregion 114 is arranged in the third quadrant Q3 and the fourth quadrant Q4.

Specifically, a quantity of the thru-holes 115 in the first quadrant Q1 is greater than any one of a quantity of the thru-holes 115 in the second quadrant Q2, a quantity of the thru-holes 115 in the third quadrant Q3, and a quantity of the thru-holes 115 in the fourth quadrant Q4. Furthermore, a part of the second subregion 112 arranged in the third quadrant Q3 has no thru-holes 115 (i.e., none of the plurality of thru-holes 115 is formed in the part of the second subregion 112 arranged in the third quadrant Q3), but the present disclosure is not limited thereto.

### Beneficial Effects of the Embodiments

In summary, the motherboard module in the present disclosure is provided with the handheld region that is pre-planned for forming the thru-holes, and the embedded depth of each of the pins for a corresponding one of the thru-holes is controlled to be within a specific ratio (e.g., the embedded depth being within a range from 75% to 95% of the hole depth), so that each of the pins does not protrude from the second surface of the handheld region that is habitually hand-held by the user, thereby enabling the motherboard module to have a hand-protection (or anti-prick) function and effectively preventing the pins from causing injury to the user.

Specifically, while the motherboard module of the present disclosure is provided with the hand-protection function, the embedded depth of each of the pins is controlled to be greater than or equal to 75% of the hole depth, so that each of the pins can be maintained to have a sufficient area for contacting a corresponding one of the solders, thereby allowing each of the pins to be stably fixed to the motherboard through the corresponding solder.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its scope.

What is claimed is:

1. A motherboard module, comprising:
a motherboard having a first surface, a second surface that is opposite to the first surface, and a surrounding lateral surface that is connected to an edge of the first surface and an edge of the second surface, wherein the motherboard defines a handheld boundary that is arranged inside of and spaced apart from the surrounding lateral surface by a distribution distance that is within a range from 2 cm to 8 cm, wherein the motherboard has a handheld region arranged between the handheld boundary and the surrounding lateral surface, and wherein the handheld region has a plurality of thru-holes recessed from the first surface to the second surface;
a plurality of solders spaced apart from each other and respectively filled in the plurality of thru-holes; and
a plurality of electronic components having a plurality of pins, wherein the plurality of pins of the plurality of electronic components are respectively inserted into the plurality of thru-holes of the handheld region from the first surface to the second surface, and a free end of each of the plurality of pins is embedded in a corresponding one of the plurality of solders;
wherein the free end of each of the plurality of pins is spaced apart from the first surface by an embedded depth that is within a range from 75% to 95% of a hole depth of a corresponding one of the plurality of thru-holes.

2. The motherboard module according to claim 1, further comprising a processor socket that is fixed onto a region surrounded by the handheld region.

3. The motherboard module according to claim 2, wherein the handheld region includes:
a first subregion arranged at one side of the processor socket, wherein the distribution distance corresponding to the first subregion is defined as a first distribution distance that is within a range from 6 cm to 8 cm;
a second subregion arranged at another side of the processor socket, wherein the first subregion and the second subregion are respectively located at two opposite sides of the processor socket, and wherein the distribution distance corresponding to the second subregion is defined as a second distribution distance that is within a range from 2 cm to 8 cm;
a third subregion connected in-between one end of the first subregion and one end of the second subregion and arranged adjacent to the processor socket, wherein the distribution distance corresponding to the third subregion is defined as a third distribution distance that is within a range from 2 cm to 5 cm; and
a fourth subregion connected in-between another end of the first subregion and another end of the second subregion and arranged away from the processor socket, wherein the distribution distance corresponding to the fourth subregion is defined as a fourth distribution distance that is within a range from 6 cm to 8 cm.

4. The motherboard module according to claim 3, wherein a quantity of the plurality of thru-holes in the first subregion is greater than any one of a quantity of the plurality of thru-holes in the second subregion, a quantity of the plurality of thru-holes in the third subregion, and a quantity of the plurality of thru-holes in the fourth subregion.

5. The motherboard module according to claim 3, wherein a counterweight of the motherboard module in the first subregion is greater than any one of a counterweight of the motherboard module in the second subregion, a counterweight of the motherboard module in the third subregion, and a counterweight of the motherboard module in the fourth subregion.

6. The motherboard module according to claim 3, wherein the motherboard defines a transversal axis and a longitudinal axis that is intersected with the transversal axis at a center of the motherboard for sequentially dividing the motherboard into a first quadrant, a second quadrant, a third quadrant, and a fourth quadrant through the transversal axis and the longitudinal axis, wherein the first subregion is arranged in the first quadrant and the fourth quadrant, the second subregion is arranged in the second quadrant and the third quadrant, the third subregion is arranged in the first quadrant and the second quadrant, and the fourth subregion is arranged in the third quadrant and the fourth quadrant, and wherein a quantity of the plurality of thru-holes in the first quadrant is greater than any one of a quantity of the plurality of thru-holes in the second quadrant, a quantity of the plurality of thru-holes in the third quadrant, and a quantity of the plurality of thru-holes in the fourth quadrant.

7. The motherboard module according to claim 6, wherein none of the plurality of thru-holes is formed in a part of the second subregion arranged in the third quadrant.

8. The motherboard module according to claim 1, wherein each of the plurality of solders has a touch end arranged adjacent to the second surface, and wherein the touch ends of the plurality of solders are coplanar with the second surfaces.

9. The motherboard module according to claim 1, wherein each of the plurality of solders has a touch end arranged adjacent to the second surface, wherein the touch end of at least one of the plurality of solders has a convex surface relative to the second surface, and wherein a height of the convex surface relative to the second surface is less than or equal to 1.5 mm.

10. The motherboard module according to claim 1, wherein each of the plurality of solders has a touch end arranged adjacent to the second surface, wherein the touch end of at least one of the plurality of solders has a concave surface relative to the second surface, and wherein a depth of the concave surface relative to the second surface is less than or equal to 1.125 mm.
